(19) United States
(12) Patent Application Publication
(10) Pub. No.: US 2025/0079390 A1
(43) Pub. Date: Mar. 6, 2025

(54) SEMICONDUCTOR PACKAGE AND METHOD OF MANUFACTURING THE SEMICONDUCTOR PACKAGE

(71) Applicant: Samsung Electronics Co., Ltd., Suwon-si (KR)

(72) Inventor: Hyunsu KIM, Suwon-si (KR)

(73) Assignee: Samsung Electronics Co., Ltd., Suwon-si (KR)

(21) Appl. No.: 18/805,670

(22) Filed: Aug. 15, 2024

(30) Foreign Application Priority Data
Sep. 4, 2023 (KR) 10-2023-0116750

(51) Int. Cl. H01L 23/00; H01L 23/498; H01L 25/065; H01L 25/16; H10B 80/00

(52) U.S. Cl. CPC H01L 24/48; H01L 21/4857; H01L 23/5386; H01L 24/85; H01L 24/92; H01L 25/0657; H01L 25/16; H01L 24/32; H01L 24/73; H01L 2224/32145; H01L 2224/32225; H01L 2224/48228; H01L 2224/48997; H01L 2224/73265; H01L 2224/85951; H01L 2224/92247; H01L 2225/0651; H10B 80/00

(57) ABSTRACT

A semiconductor package includes a package substrate having substrate pads spaced apart from each other in a first direction and an upper insulation layer on an upper surface of the package substrate, the upper insulation layer defining a recess that exposes the substrate pads; a dam structure extending on the upper insulation layer to surround the recess; semiconductor chips stacked on the upper insulation layer of the package substrate such that a first surface on which chip pads are formed faces upward, semiconductor chips spaced apart from the dam structure in a second direction perpendicular to the first direction; bonding wires connecting the substrate pads to the chip pads of the semiconductor chips; and an underfill member filling an interior of the recess to cover an end portion of each of the bonding wires and each of the substrate pads.

### PRIORITY STATEMENT

This application claims priority to and benefit under 35 U.S.C. § 119 to Korean Patent Application No. 10-2023-0116750, filed on Sep. 4, 2023 in the Korean Intellectual Property Office (KIPO), the contents of which are herein incorporated by reference in their entirety.

### BACKGROUND

Example embodiments relate to semiconductor packages and methods of manufacturing the semiconductor packages. More particularly, example embodiments relate to semiconductor packages having a plurality of stacked chips and manufacturing methods thereof.

In a wire bonding process for connecting between a package substrate and a semiconductor chip mounted on the package substrate by using a metal wire, a process of forming an additional bump on a bonding portion of the metal wire may be performed to increase a bondability of the metal wire. However, the process of forming the additional bump may exert a physical downward force on the metal wire, so that the metal wire makes contact with a side of the stacked semiconductor chips, thereby causing a failure such as leakage and a short of current. Additionally, the process of forming the additional bump has limitation in improving a bonding strength of the metal wire because the process does not increase an actual bonding area of the metal wire.

### SUMMARY

Example embodiments provide a semiconductor package having an improved bonding reliability.

Example embodiments provide a method of manufacturing the semiconductor package.

According to some example embodiments, a semiconductor package includes a package substrate including a plurality of substrate pads spaced apart from each other in a first direction and an upper insulation layer on an upper surface of the package substrate, the upper insulation layer defining a recess that exposes the plurality of substrate pads; a dam structure extending on the upper insulation layer to surround the recess; a plurality of semiconductor chips stacked on the upper insulation layer, each semiconductor chip of the plurality of semiconductor chips including a first surface facing upwards and each chip pad of a plurality of chip pads on a respective first surface, the plurality of semiconductor chips being spaced apart from the dam structure in a second direction perpendicular to the first direction; a plurality of bonding wires connecting the plurality of substrate pads to the plurality of chip pads of the plurality of semiconductor chips; and an underfill member filling an interior of the recess to cover an end portion of each of the plurality of bonding wires and each of the plurality of substrate pads.

According to some example embodiments, a semiconductor package includes a package substrate having a first side portion extending in a first direction and a second side portion facing with the first side portion, the package substrate having a plurality of substrate pads spaced apart from each other along the first side portion and an upper insulation layer defining a recess that exposes the plurality of substrate pads; a dam structure extending on the upper insulation layer to surround the recess; a plurality of semiconductor chips stacked on an upper surface of the package substrate such that a first surface on which a plurality of chip pads are formed faces upward, the plurality of semiconductor chips being spaced apart from a side portion of the dam structure in a second direction perpendicular to the first direction; a plurality of bonding wires connecting the plurality of substrate pads to the plurality of chip pads of the plurality of semiconductor chips; and an underfill member filling an interior of the recess to cover an end portion of each of the plurality of bonding wires and each of the plurality of substrate pads.

According to some example embodiments, a semiconductor package includes a package substrate having a plurality of uppermost wires and an upper insulation layer on an upper surface of the package substrate, the upper insulation layer defining a recess exposing the plurality of uppermost wires, a plurality of substrate pads on the plurality of exposed uppermost wires, and a dam structure extending on the upper insulation layer to surround the recess; a plurality of semiconductor chips stacked on the upper surface of the package substrate by a plurality of adhesive films such that a first surface on which a plurality of chip pads are formed faces upward; a plurality of bonding wires connecting the plurality of substrate pads to the plurality of chip pads of the plurality of semiconductor chips; and an underfill member filling an interior of the recess to cover an end portion of each of the plurality of bonding wires and each of the plurality of substrate pads.

According to some example embodiments, a semiconductor package may include a package substrate providing an upper insulation layer having a recess that exposes a plurality of substrate pads and a dam structure surrounding the recess, a plurality of semiconductor chips mounted on the upper insulation layer of the package substrate, a plurality of bonding wires connecting a plurality of chip pads to the plurality of substrate pads, and an underfill member filling an interior of the recess. The underfill member may cover each of the plurality of substrate pads and an end portion of each of the plurality of bonding wires bonded to each of the plurality of substrate pads.

Accordingly, the underfill member may strengthen the bondability of wire bonding without applying physical force to the bonding wire, thereby preventing or reducing in likelihood defects caused by contact between the bonding wire and the semiconductor chip. Additionally, the underfill member may strengthen the bondability of the bonding wire regardless of the actual bonding area of the bonding wire.

### BRIEF DESCRIPTION OF THE DRAWINGS

FIG. 1 is a cross-sectional view illustrating a semiconductor package in accordance with some example embodiments.

FIG. 2 is an enlarged cross-sectional view illustrating the ‘A’ portion of FIG. 1.

FIG. 3 is a plan view illustrating a semiconductor package of FIG. 1.

FIG. 4 is a plan view illustrating a package substrate of a semiconductor package of FIG. 1.

FIG. 5 is a cross-sectional view taken along the line C-C′ in FIG. 4.

FIGS. 6 to 22 are views illustrating a method of manufacturing a semiconductor package in accordance with some example embodiments.

### DETAILED DESCRIPTION OF EXAMPLE EMBODIMENTS

When the terms “about” or “substantially” are used in this specification in connection with a numerical value, it is intended that the associated numerical value includes a manufacturing or operational tolerance (e.g., ±10%) around the stated numerical value. Moreover, when the words “about” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

Hereinafter, some example embodiments will be explained in detail with reference to the accompanying drawings.

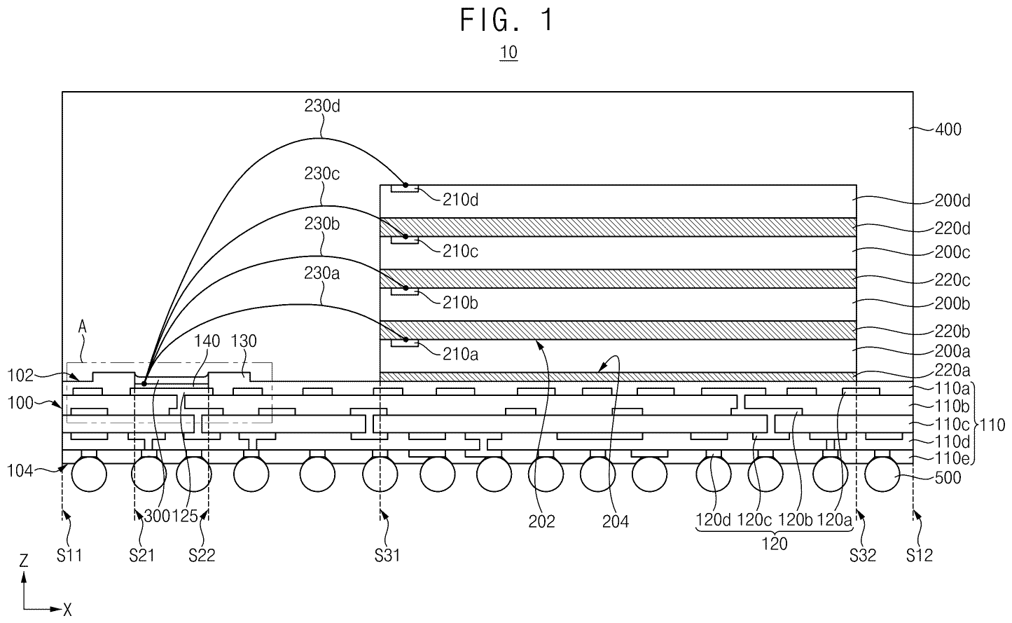

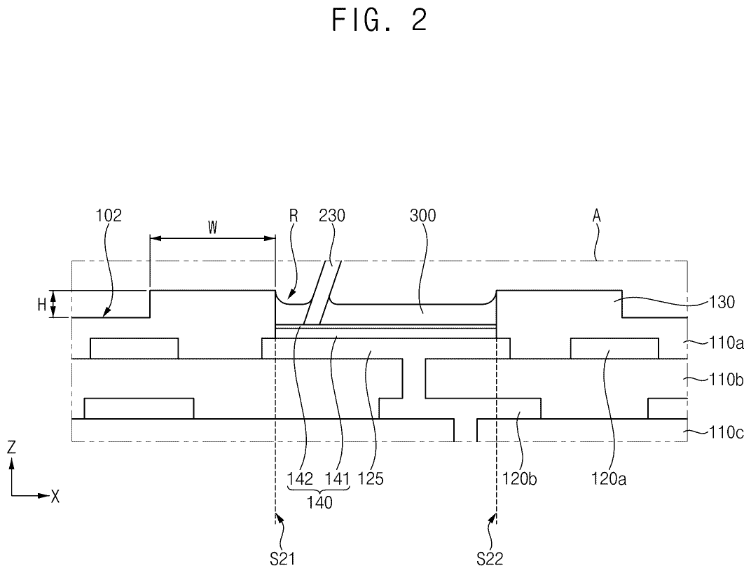

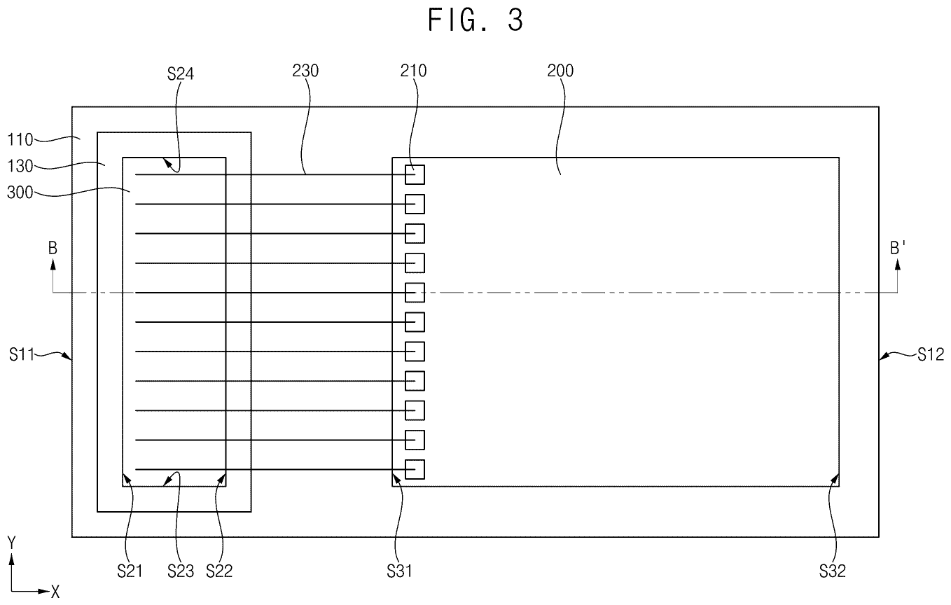

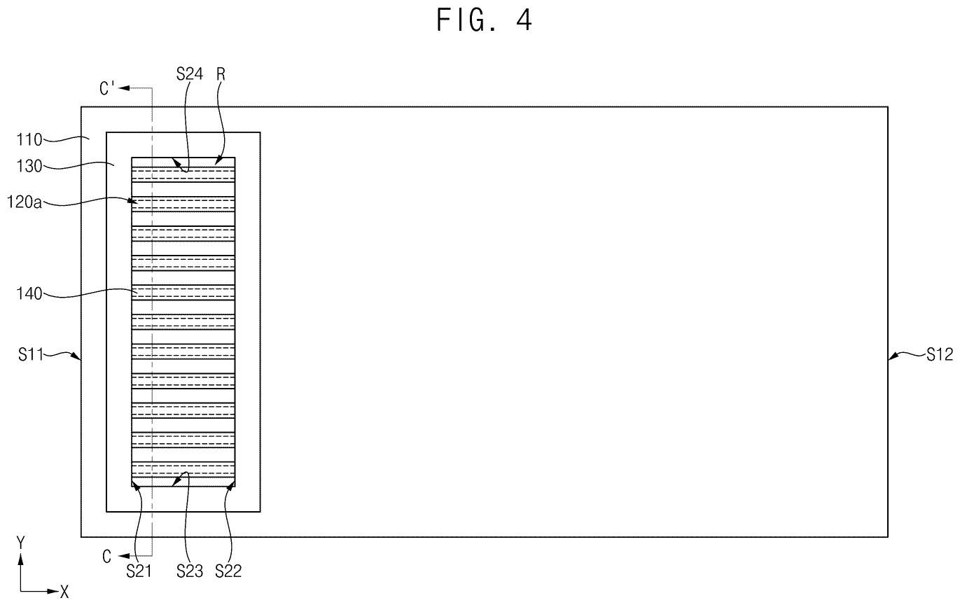

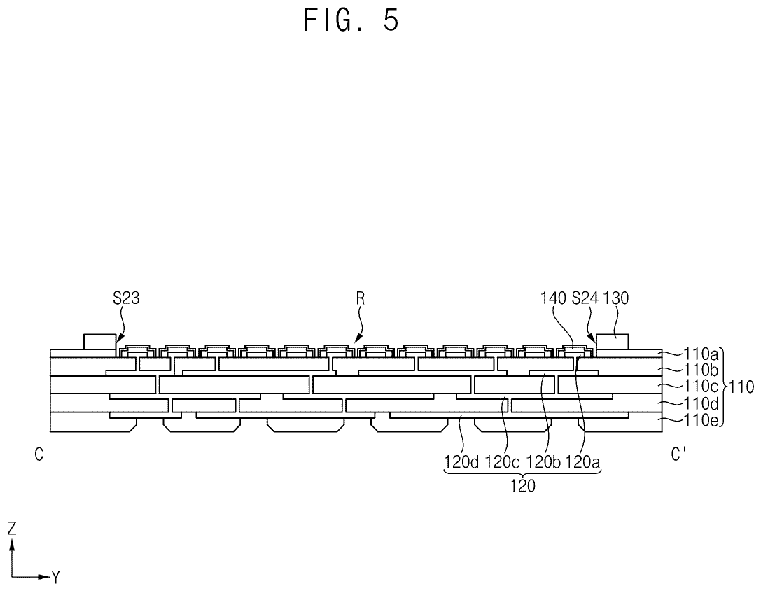

FIG. 1 is a cross-sectional view illustrating a semiconductor package in accordance with some example embodiments. FIG. 2 is an enlarged cross-sectional view illustrating the ‘A’ portion of FIG. 1. FIG. 3 is a plan view illustrating the semiconductor package of FIG. 1. FIG. 4 is a plan view illustrating a package substrate of the semiconductor package of FIG. 1. FIG. 5 is a cross-sectional view taken along the line C-C′ in FIG. 4.

Referring to FIGS. 1 to 5, a semiconductor package 10 may include a package substrate 100, a plurality of semiconductor chips 200 stacked on the package substrate 100 and an underfill member 300 disposed in a recess R of the package substrate 100. Additionally, the semiconductor package 10 may further includes a plurality of bonding wires 230. The semiconductor package 10 may further include a molding member 400 and a plurality of external connection members 500.

Additionally, the semiconductor package 10 may be a multi-chip package (MCP) including semiconductor chips of the same or different types. The semiconductor package 10 may be a system in package (SIP) having an independent function by stacking or arranging multiple chips in one package.

In some example embodiments, the package substrate 100 may be a multi-layer circuit board having an upper surface 102 and a lower surface 104 facing each other. For example, the package substrate 100 may be a printed circuit board (PCB) including wires provided in each of a plurality of insulating layers and vias for connecting the wires.

As illustrated in FIGS. 1 and 5, the package substrate 100 may include a plurality of insulation layers 110 and a plurality of wires 120a, 120b, 120c, and 120d respectively provided on the insulation layers.

In particular, the package substrate 100 may include a first to fifth insulation layer 110a, 110b, 110c, 110d, and 110e sequentially stacked. The first insulation layer 110a may be an upper cover insulation layer, and the second insulation layer 110b may be an upper insulation layer, and the third insulation layer 110c may be a core layer, and the fourth insulation layer 110d may be a lower insulation layer, and the fifth insulation layer 110e may be a lower cover insulation layer.

For example, the insulation layer may include an insulation material such as a thermosetting resin such as epoxy resin or a thermoplastic resin such as polyimide. The insulation layer may include a resin impregnated into a core material such as organic fiber (glass fiber), for example, prepreg, FR-4, or BT (Bismaleimide Triazine). The insulation layer may include a solder resist.

A first wire 120a may be formed on an upper surface of the second insulation layer 110b, and a second wire 120b may be formed on an upper surface of the third insulation layer 110c. A third wire 120c may be formed on a lower surface of the third insulation layer 110c, and a fourth wire 120d may be formed on a lower surface of the fourth insulation layer 110d. For example, the wire may include metal materials such as copper (Cu), aluminum (Al), etc. The arrangements and numbers of the insulation layers and the wires are provided as examples, and it will be understood that the present inventive concept is not limited thereto.

As illustrated in FIGS. 3 and 4, the package substrate 100 may extend in a first direction (X direction). The package substrate 100 may have a first side portion S11 extending in a second direction (Y direction) perpendicular to the first direction (X direction) and a second side portion S12 facing the first side portion S11.

The package substrate 100 may have the recess R adjacent to the first side portion S11 and exposing a plurality of conductive wires 125 that are portions of the first wire 120a. The recess R may expose at least a portion of an upper surface of each of the plurality of conductive wires 125. The recess R may be provided in the first insulation layer 110a, which is an uppermost insulation layer of the package substrate 100. The first wire 120a may be an uppermost wire provided in the first insulation layer 110a.

For example, the recess R may have a rectangular shape, for example a square shape, with a plurality of side portions. The recess R may include a first inner wall S21 and a second inner wall S22 that extend in the second direction (Y direction) of the package substrate 100. Additionally, the recess R may include a third inner wall S23 and a fourth inner wall S24 that extend in the first direction (X direction).

The plurality of conductive wires 125 may be arranged within of the recess R to be spaced apart from each other along the second direction (Y direction). For example, the plurality of conductive wires 125 may be disposed between the first inner wall S21 and the second inner wall S22 of the recess R to be arranged at regular intervals along the first inner wall S21 and the second inner wall S22.

A dam structure 130 may be disposed on the upper surface 102 of the package substrate 100 to surround the recess R. For example, the dam structure 130 may be arranged to surround the plurality of inner walls S21, S22, S23, and S24 of the recess R. The dam structure 130 may include an insulation material the same as the first insulation layer 110a. For example, the dam structure 130 may include a solder resist.

The dam structure 130 may be a protruding portion having a first height H from the upper surface 102 of the package substrate 100. For example, the first height H may be within a range of about 5 μm to about 10 μm. The dam structure 130 may have a first width W from the plurality of inner walls S21, S22, S23, and S24 to a respective outer surface of the dam structure 130. For example, the first width W may be within a range of about 50 μm to about 150 μm.

A plurality of substrate pads as bonding leads 140 may be respectively disposed on the plurality of conductive wires 125 exposed by the recess R. For example, the plurality of substrate pads 140 may cover upper surfaces of the plurality of conductive wires 125 exposed by the recess R, respectively.

The plurality of substrate pads 140 may be arranged within the recess R to be spaced apart from each other along the second direction (Y direction). For example, the plurality of substrate pads 140 may be disposed at regular intervals along the first inner wall S21 and the second inner wall S22.

Each of the plurality of substrate pads 140 may extend along the first direction (X direction). For example, the plurality of substrate pads 140 may be disposed between the first inner wall S21 and the second inner wall S22 of the recess R to be in contact with the first inner wall S21 and the second inner wall S22 of the recess R.

Each of the plurality of substrate pads 140 may include a plurality of metal layers. For example, each of the plurality of substrate pads 140 may include a first conductive layer 141 disposed on each of the plurality of conductive wires 125 and a second conductive layer 142 disposed on the first conductive layer 141. For example, the first conductive layer 141 may include nickel (Ni), and the second conductive layer 142 may include gold (Au).

In some example embodiments, the plurality of semiconductor chips 200 may be attached to the package substrate 100 by a plurality of adhesive films 220. For example, the plurality of semiconductor chips 200a, 200b, 200c, and 200d may be sequentially stacked on the package substrate 100 using the plurality of adhesive films 220a, 220b, 220c, and 220d.

The plurality of semiconductor chips 200 may be disposed adjacent to the second side portion S12 of the package substrate 100. The plurality of semiconductor chips 200 may be arranged to be spaced apart from the dam structure 130 of the package substrate 100 in the first direction (X direction).

The plurality of semiconductor chips 200 may include a memory chip including a memory circuit. For example, the plurality of semiconductor chips 200 may include volatile memory devices such as SRAM devices or DRAM devices and/or a non-volatile memory device such as flash memory devices, PRAM devices, MRAM devices or RRAM devices. Alternatively, the plurality of semiconductor chips 200 may include a logic chip having a logic circuit. The logic chip may be a controller that controls memory chips. The logic chip may be a processor chip such as an ASIC or an application processor (AP) as a host such as CPU, GPU, or SOC.

The plurality of semiconductor chips 200a, 200b, 200c, and 200d may have a rectangular shape, for example a square shape with four side portions when viewed in a plan view. For example, the plurality of semiconductor chips 200 may include a first to fourth semiconductor chip 200a, 200b, 200c, and 200d. Each of the first to fourth semiconductor chips 200a, 200b, 200c, and 200d may have a first side portion S31 extending along the second direction (Y direction) and a second side portion S32 facing with the first side portion S31. Each of a plurality of chip pads 210a, 210b, 210c, and 210d may be exposed from a front surface 202 of each of the first to fourth semiconductor chips 200a, 200b, 200c, and 200d, and may be disposed along the first side portion S31.

The plurality of semiconductor chips 200 may be attached to the package substrate 100 through a die attach process using a plurality of adhesive films such as a die attach film (DAF). For example, the plurality of semiconductor chips 200a, 200b, 200c, and 200d may be sequentially attached to the upper surface 102 of the package substrate 100 using a plurality of adhesive films 220a, 220b, 220c, and 220d, which are die attach films (DAF). The plurality of semiconductor chips 200a, 200b, 200c, and 200d may be disposed such that a backside surface 204, that is, an inactive surface opposite to the front surface 202 faces the package substrate 100.

For example, each of the plurality of adhesive films 220a, 220b, 220c, and 220d may be attached to the backside surface 204 of each of the plurality of semiconductor chips 200a, 200b, 200c, and 200d, and the plurality of semiconductor chips 200a, 200b, 200c, and 200d where the plurality of adhesive films 220a, 220b, 220c, and 220d are attached may be sequentially attached to the package substrate 100 by a thermal compression process. The plurality of semiconductor chips 200a, 200b, 200c, and 200d may be pressed by a die attaching tool, and heated to a high temperature by a heater block in a support system supporting the package substrate 100.

The number, size and the arrangement, etc. of the plurality of semiconductor chips are provided as examples, and the present inventive concepts are not limited thereto. Also, although only a few chip pads are shown in the drawings, it will be understood that the structure, shape, and arrangement of the chip pads are provided as examples, and the present inventive concepts are not limited thereto.

In some example embodiments, the plurality of semiconductor chips 200 may be electrically connected to the package substrate 100 by the plurality of bonding wires 230. For example, the plurality of bonding wires 230 may include a metal material. For example, the plurality of bonding wires 230 may include gold (Au).

For example, the plurality of bonding wires 230 may include first to fourth bonding wires 230a, 230b, 230c, and 230d. Each of the first to fourth bonding wires 230a, 230b, 230c, and 230d may have a first end portion in contact with each of the plurality of substrate pads 140 and a second end portion in contact with each of the plurality of chip pads 210.

The plurality of bonding wires 230 may electrically connect the plurality of substrate pads 140 to the plurality of chip pads 210, respectively. For example, the plurality of first bonding wires 230a may electrically connect the plurality of substrate pads 140 in the recess R to the plurality of first chip pads 210a of the first semiconductor chip 200a. Likewise, the second to fourth bonding wires 230b, 230c, and 230d may electrically connect the plurality of substrate pads 140 to the plurality of second to fourth chip pads 210b, 210c, and 210d, respectively.

In some example embodiments, the underfill member 300 may at least partially fill the recess R to cover the plurality of substrate pads 140 and the end portions of the plurality of conductive members respectively bonded to the plurality of substrate pads 140. The underfill member 300 may include a thermosetting material that has fluidity before being heated, but hardens after being heated. For example, the underfill member 300 may include an adhesive material including an epoxy material.

The underfill member 300 may reinforce a connection between the plurality of bonding wires 230 and the plurality of substrate pads 140. For example, the underfill member 300 may secure the end portions of the plurality of bonding wires to prevent or reduce in likelihood external force from acting on the connection between the plurality of bonding wires 230 and the plurality of substrate pads 140.

The underfill member 300 may be in contact with the dam structure 130 of the package substrate 100. The dam structure 130 may prevent or reduce in likelihood the underfill member 300 which has fluidity from overflowing out of the recess R of the package substrate 100 before the underfill member 300 is heated. In some example embodiments a height of the underfill member 300 may be less than a height of the dam structure 130.

In some example embodiments, the molding member 400 may be disposed on the upper surface 102 of the package substrate 100 to cover a plurality of semiconductor chips 200 and the plurality of bonding wires 230. For example, the molding member may include an epoxy molding compound (EMC).

In some example embodiments, the plurality of external connection members 500 may be provided on the plurality of fourth wires as external connection pads 120d disposed on the lower surface 104 of the package substrate 100. For example, the plurality of external connection members 500 may include solder balls.

As mentioned above, the semiconductor package 10 may include the package substrate 100 having the recess R that exposes the portion of each of the plurality of conductive wires 125, the plurality of substrate pads 140 disposed on the plurality of conductive wires 125 and the dam structure 130 surrounding the recess R, the plurality of semiconductor chips 200 mounted on the upper surface 102 of the package substrate 100, the plurality of bonding wires 230 connecting the plurality of substrate pads 140 and the plurality of chip pads 210, and the underfill member 300 filling the interior of the recess R of the package substrate 100. Additionally, the semiconductor package 10 may further include the molding member 400 and the external connection members 500.

The underfill member 300 may cover the plurality of substrate pads 140 and the end portions of the plurality of bonding wires 230 respectively bonded to the plurality of substrate pads 140.

Accordingly, the underfill member 300 may strengthen the bondability of wire bonding without applying a physical force to the wire, thereby preventing or reducing in likelihood defects caused by contact between the wire and the semiconductor chip. Additionally, the underfill member 300 may strengthen the bondability of the wire bonding regardless of the actual bonding area of the wire bonding.

Hereinafter, methods of manufacturing semiconductor packages, for example some example embodiments with reference to FIG. 1 will be described.

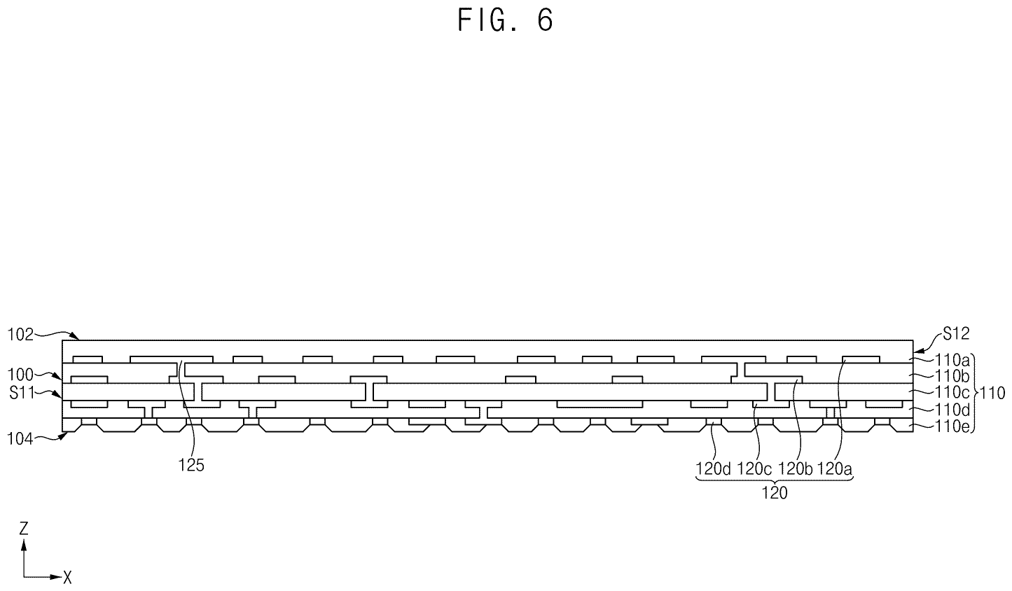

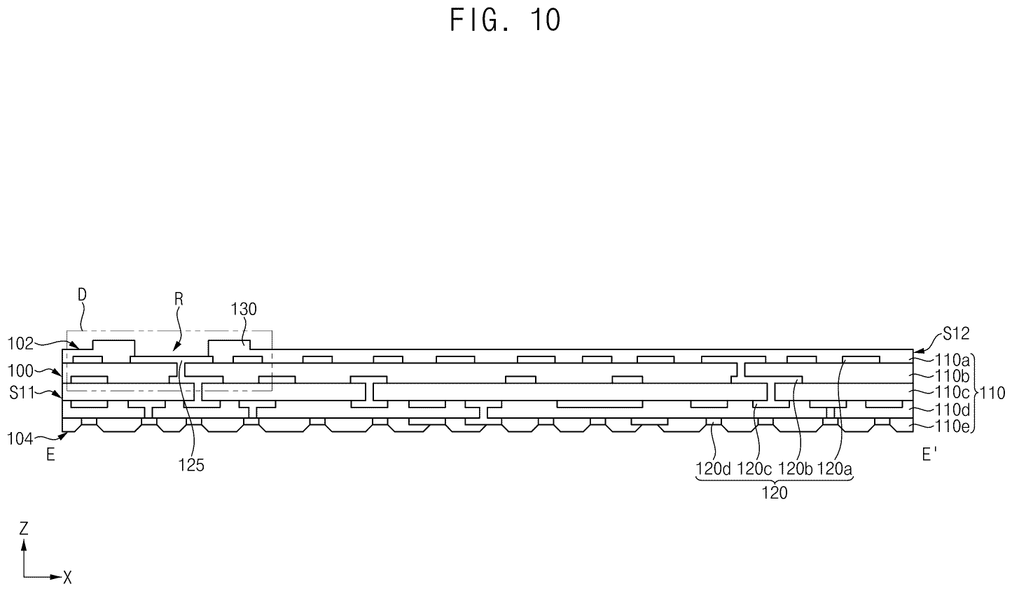

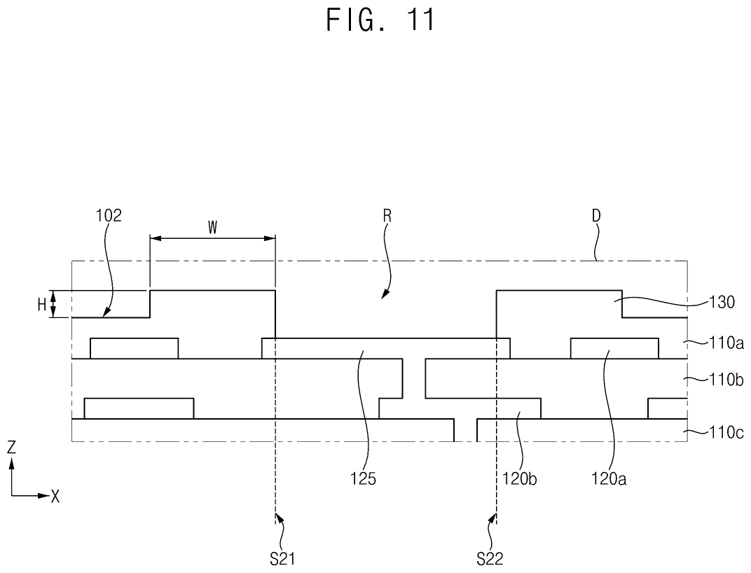

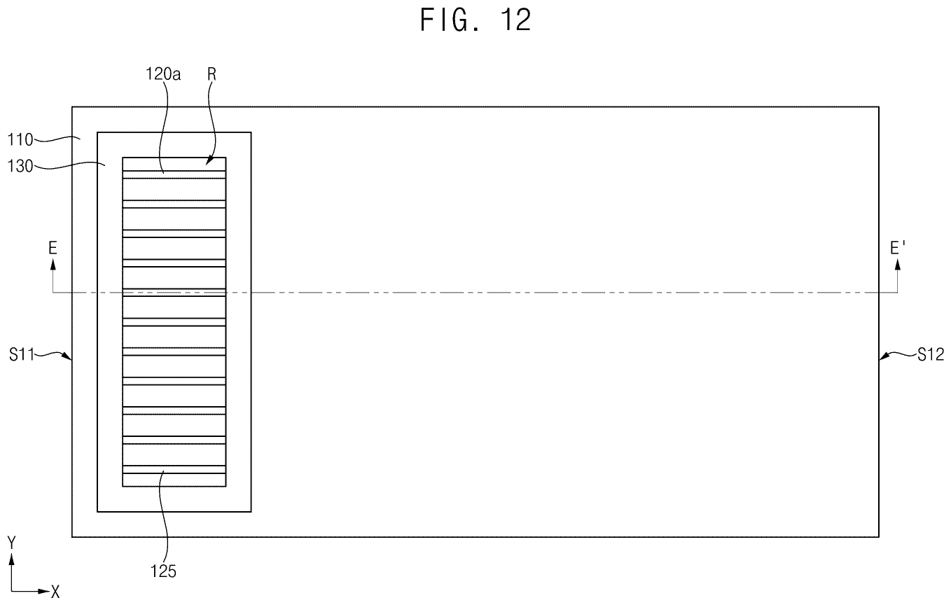

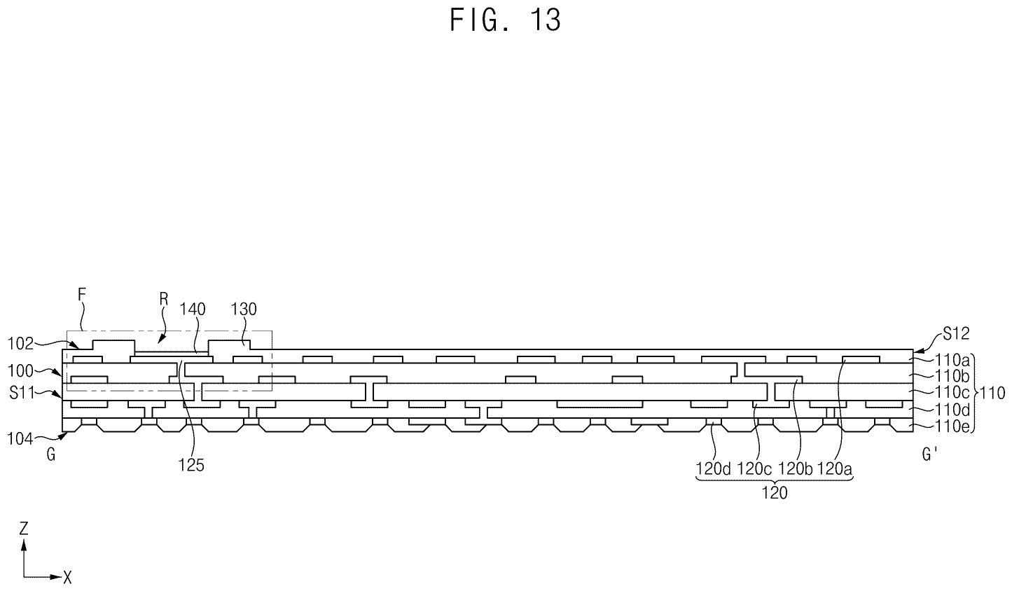

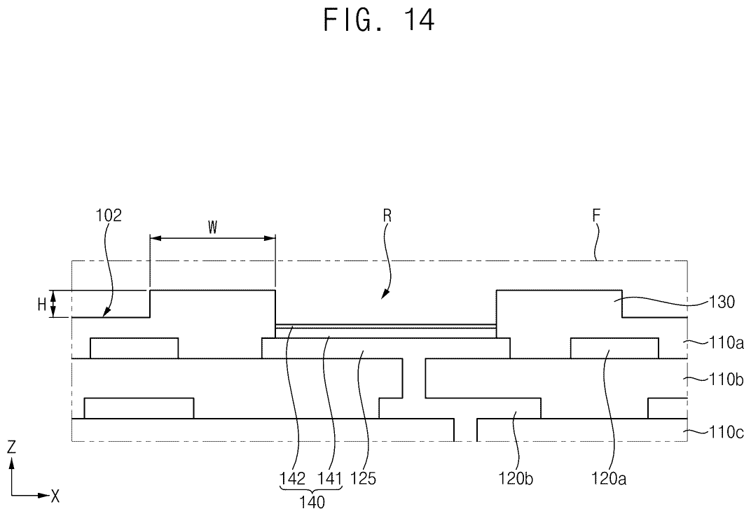

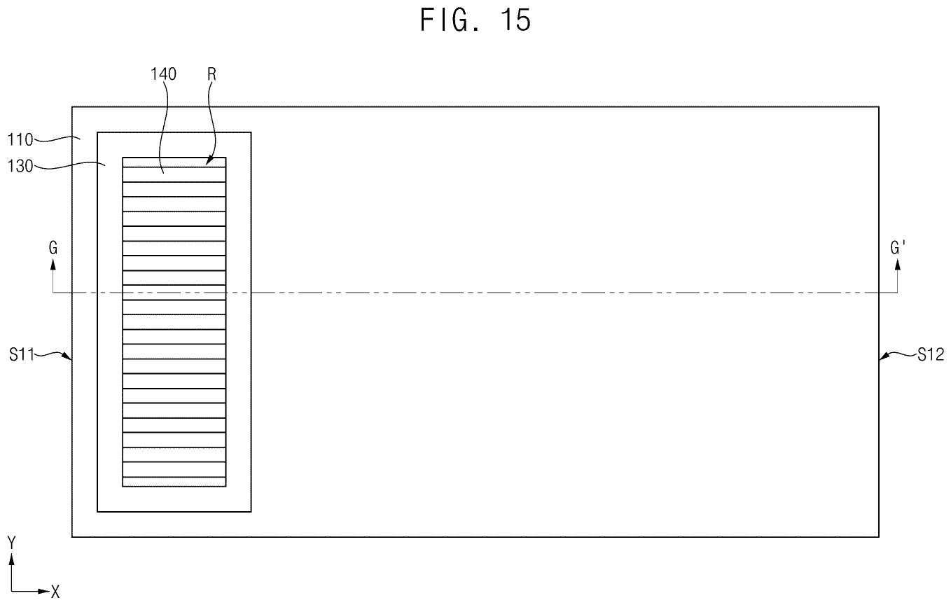

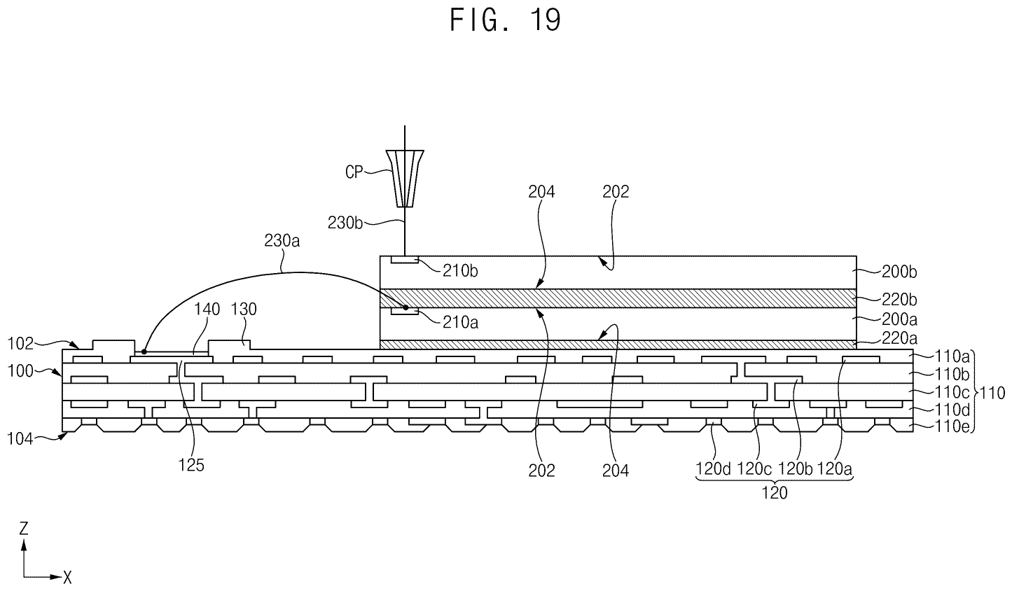

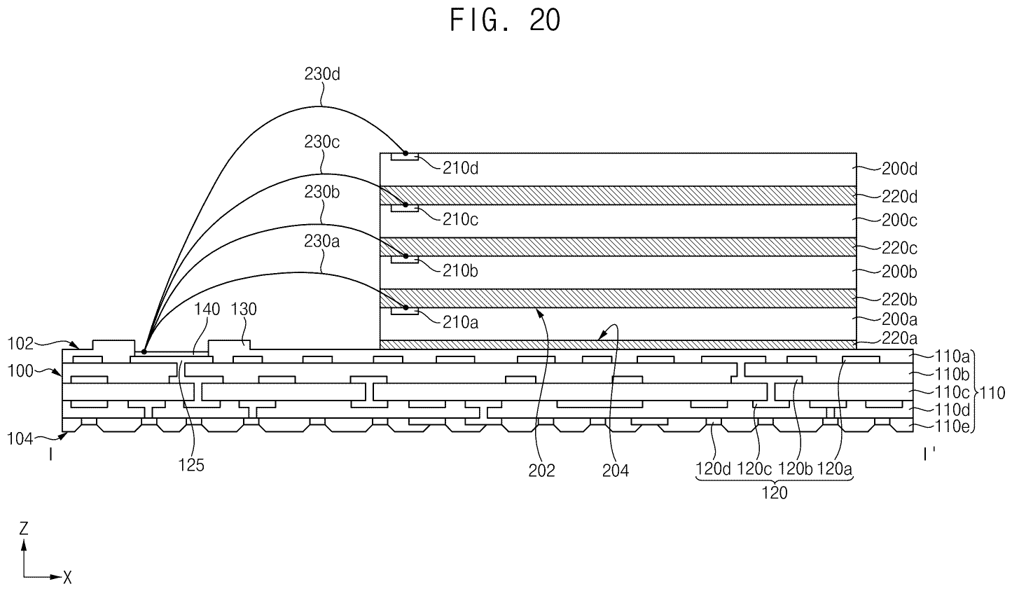

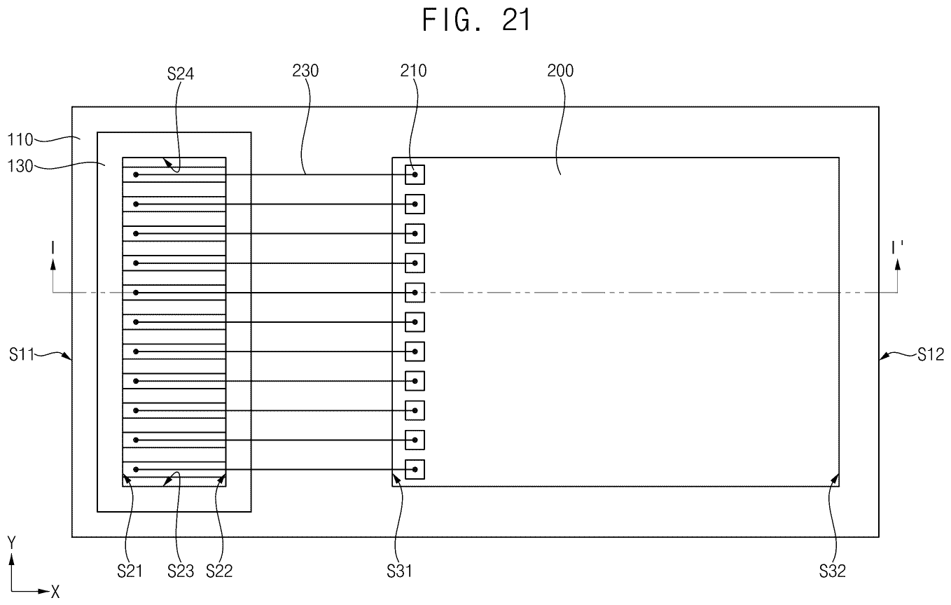

FIGS. 6 to 10, FIGS. 16 to 19 and FIG. 22 are cross-sectional views illustrating a method of manufacturing a semiconductor package in accordance with some example embodiments. FIG. 11 is an enlarged cross-sectional view illustrating the ‘D’ portion of FIG. 10. FIG. 12 is a plan view illustrating a package substrate of a semiconductor package in accordance with some example embodiments. FIG. 14 is an enlarged cross-sectional view illustrating the ‘F’ portion of FIG. 13. FIG. 15 is a plan view illustrating a package substrate having a plurality of substrate pads in accordance with some example embodiments. FIG. 21 is a plan view illustrating a package substrate having a plurality of semiconductors and a plurality of bonding wires in accordance with some example embodiments. FIG. 10 is a cross-sectional view taken along the line E-E′ in FIG. 12. FIG. 13 is a cross-sectional view taken along the line G-G′ in FIG. 15. FIG. 20 is a cross-sectional view taken along the line I-I′ in FIG. 21.

Referring to FIG. 6, a package substrate 100 having a plurality of insulation layers 110 and a plurality of wires 120 may be provided.

In some example embodiments, the package substrate 100 may be a multi-layer circuit board having an upper surface 102 and a lower surface 104 facing each other. For example, the package substrate 100 may be a printed circuit board (PCB) including wires provided in each of a plurality of insulating layers and vias for connecting the wires.

The package substrate 100 may provide a first side portion S11 extending in a second direction (Y direction) perpendicular to the first direction (X direction) and a second side portion S12 facing the first side portion S11.

In particular, the package substrate 100 may include a plurality of insulation layers 110 and a plurality of wires 120a, 120b, 120c, and 120d respectively provided on the insulation layers.

The package substrate 100 may include first to fifth insulation layer 110a, 110b, 110c, 110d, and 110e sequentially stacked. The first insulation layer 110a may be an upper cover insulation layer, and the second insulation layer 110b may be an upper insulation layer, and the third insulation layer 110c may be a core layer, and the fourth insulation layer 110d may be a lower insulation layer, and the fifth insulation layer 110e may be a lower cover insulation layer.

For example, the insulation layer may include an insulation material such as a thermosetting resin such as epoxy resin or a thermoplastic resin such as polyimide. The insulation layer may include a resin impregnated into a core material such as organic fiber (glass fiber), for example, prepreg, FR-4, or BT (Bismaleimide Triazine). The insulation layer may include solder resist.

A first wire 120a may be formed on an upper surface of the second insulation layer 110b, and a second wire 120b may be formed on an upper surface of the third insulation layer 110c. A third wire 120c may be formed on a lower surface of the third insulation layer 110c, and a fourth wire 120d may be formed on a lower surface of the fourth insulation layer 110d. For example, the wire may include metal materials such as copper (Cu), aluminum (Al), etc. The arrangements and numbers of the insulation layers and the wires are provided as examples, and it will be understood that the present inventive concepts are not limited thereto.

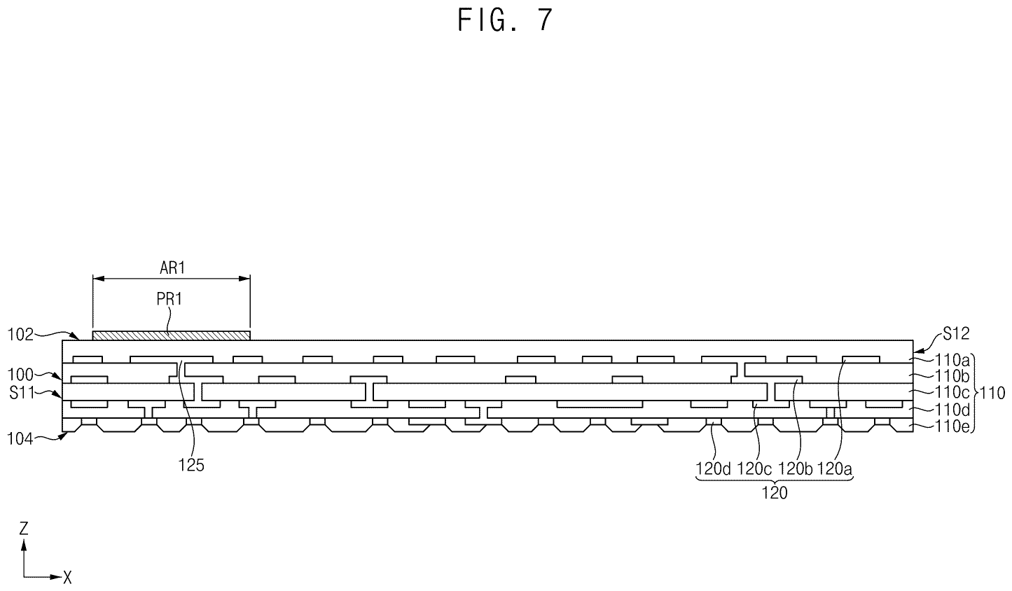

Referring to FIGS. 7 to 12, a recess R may be formed in the first insulation layer as the upper insulation layer 110a to expose a portion of each of a plurality of conductive wires 125, and a dam structure 130 surrounding the recess R may be formed on the first insulation layer 110a. That is to say, in some example embodiments the dam structure 130 may be formed or defined as a single contiguous structure with the first insulation layer 110a.

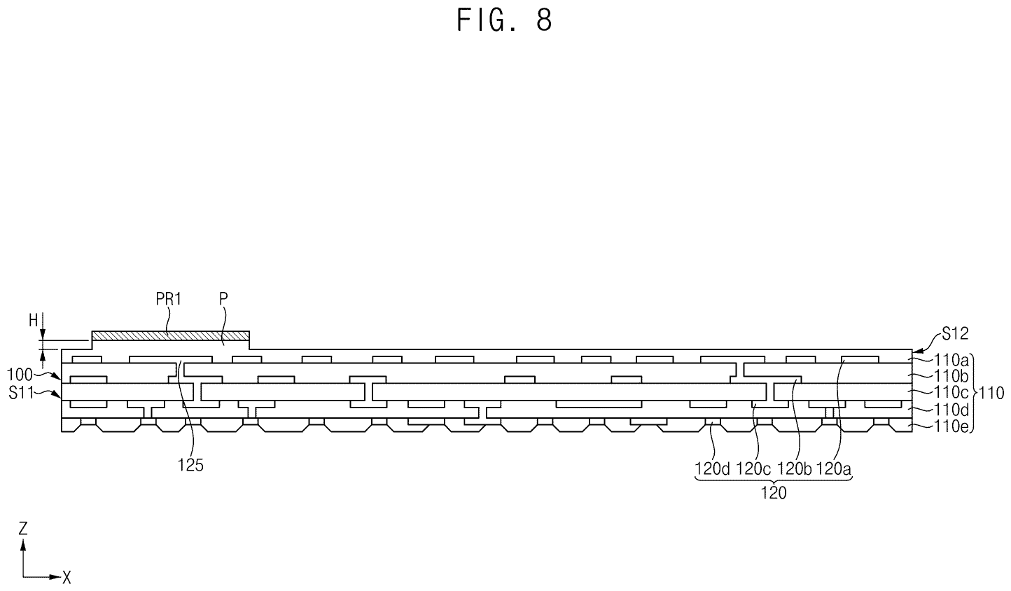

As illustrated in FIGS. 7 and 8, a first photoresist pattern PR1 may be formed to cover a first region ARI including a region for the recess R and a region for the dam structure 130, and then a protruding portion P having a first height H may be formed by performing a first etching process on the first insulation layer 110a.

For example, in consideration of the depth of the recess R, the first insulation layer 110a, which is the uppermost insulating layer, may be formed to be thicker than other insulation layers 110b, 110c, 110d, and 110e. And then, a photoresist layer may be dispensed to cover the upper surface 102 of the package substrate 100. And then, an exposure process and a development process may be performed to form the first photoresist pattern PR1 covering the first region AR1. The first region ARI may be a region where the recess R and the dam structure 130 are formed. And then, the first etching process using the first photoresist pattern PR1 as an etching mask may be performed to form the protruding portion P to partially remove the upper surface of the first insulation layer 110a.

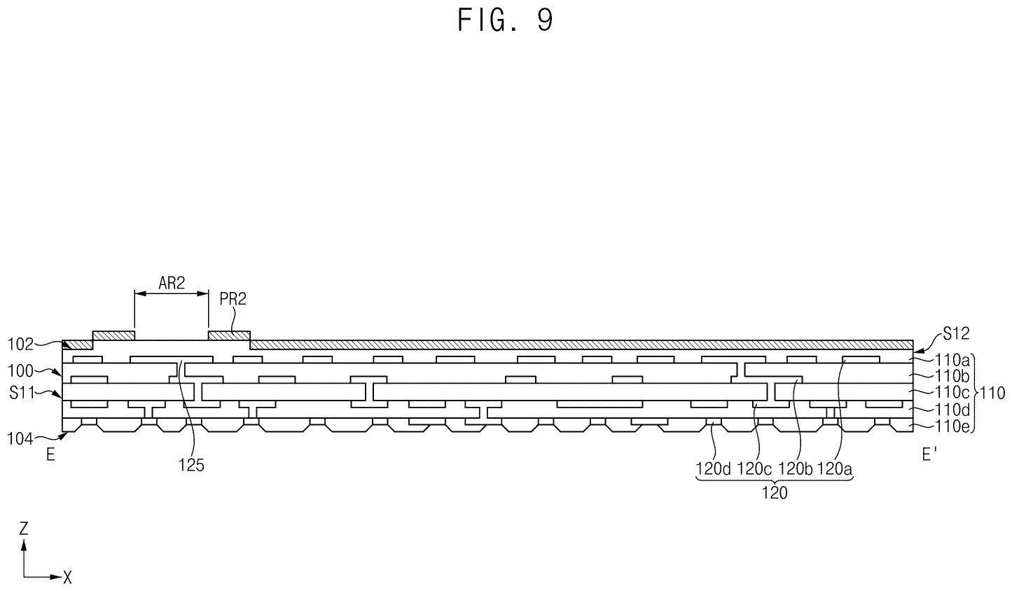

As illustrated in FIGS. 9 and 10, a second photoresist pattern PR2 may be formed to expose a second region AR2 where the recess R is to be formed, and then a second etching process on the second region AR2 may be performed to form the recess R and the dam structure 130 surrounding the recess R on the first insulation layer 110a.

As illustrated in FIGS. 11 and 12, the recess R may be formed adjacent to the first side portion S11 of the package substrate 100 to expose portions of the plurality of conductive wires 125 that are portions of the first wire 120a. The recess R may expose at least a portion of an upper surface of each of the plurality of conductive wires 125. The recess R may be disposed in the first insulation layer 110a which is the uppermost insulation layer of the package substrate 100. The first wire 120a may be the uppermost wire disposed in the first insulation layer as the uppermost insulation layer 110a.

For example, the recess R may have a rectangular shape, for example a square shape, with a plurality of side portions. The recess R may include a first inner wall S21 and a second inner wall S22 that extend in the second direction (Y direction) of the package substrate 100. Additionally, the recess R may include a third inner wall S23 and a fourth inner wall S24 that extend in the first direction (X direction).

The plurality of conductive wires 125 may be arranged within of the recess R to be spaced apart from each other along the second direction (Y direction). For example, the plurality of conductive wires 125 may be disposed between the first inner wall S21 and the second inner wall S22 of the recess R to be arranged at regular intervals along the first inner wall S21 and the second inner wall S22.

A dam structure 130 may be disposed on the upper surface 102 of the package substrate 100 to surround the recess R. For example, the dam structure 130 may be arranged to surround the plurality of inner walls S21, S22, S23, and S24 of the recess R. The dam structure 130 may include an insulation material the same as the first insulation layer 110a. For example, the dam structure 130 may include a solder resist.

The dam structure 130 may be a protruding portion having a first height H from the upper surface 102 of the package substrate 100. For example, the first height H may be within a range of about 5 μm to about 10 μm. The dam structure 130 may have a first width W from the plurality of inner walls S21, S22, S23, and S24. For example, the first width W may be within a range of about 50 μm to about 150 μm.

Referring to FIGS. 13 to 15, a plurality of substrate pads 140 may be formed on the plurality of conductive wires 125 by performing an electroplating process in the recess R.

The plurality of substrate pads as bonding leads 140 may be respectively disposed on the plurality of conductive wires 125 exposed by the recess R. For example, the plurality of substrate pads 140 may cover upper surfaces of the plurality of conductive wires 125 exposed by the recess R, respectively.

Each of the plurality of substrate pads 140 may include a plurality of metal layers. For example, each of the plurality of substrate pads 140 may include a first conductive layer 141 disposed on each of the plurality of conductive wires 125 and a second conductive layer 142 disposed on the first conductive layer 141. For example, the first conductive layer 141 may include nickel (Ni), and the second conductive layer 142 may include gold (Au).

For example, the first conductive layer 141 may be formed by flowing current through a conductive line and depositing particles of nickel (Ni) on the plurality of conductive wires 125. And then, the second conductive layer 142 may be formed by flowing a current through a conductive line to deposit particles of gold (Au) on the first conductive layer 141.

As illustrated in FIG. 14, the plurality of substrate pads 140 may be extended in the first direction (X direction), respectively. For example, the plurality of substrate pads 140 may be disposed between the first inner wall S21 and the second inner wall S22 of the recess R to contact the first inner wall S21 and the second inner wall S22 of the recess R.

As illustrated in FIG. 15, the plurality of substrate pads 140 may be arranged within the recess to be spaced apart from each other along the second direction (Y direction). For example, the plurality of substrate pads 140 may be disposed at regular intervals along the first inner wall S21 and the second inner wall S22.

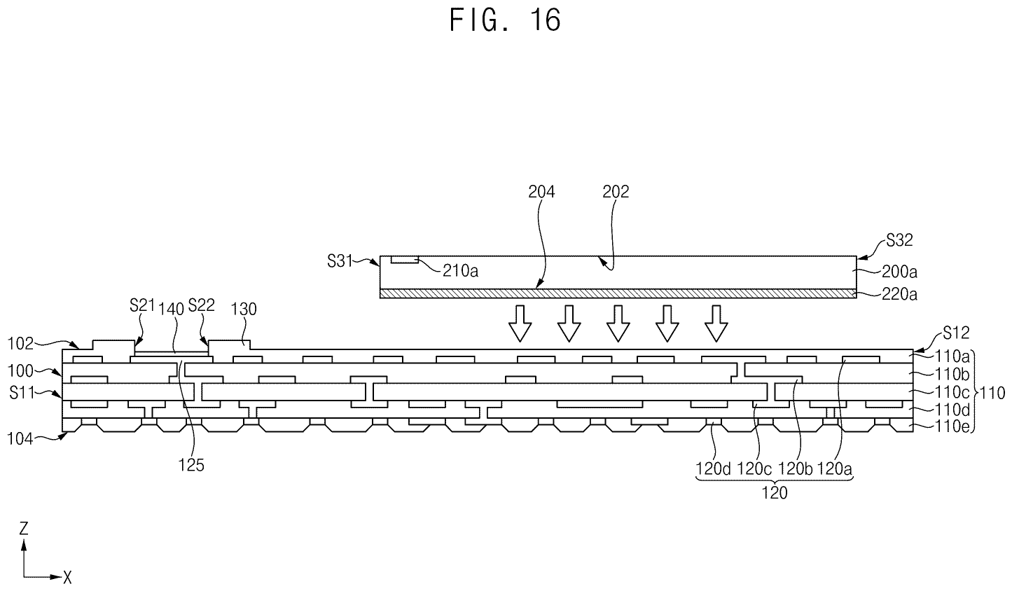

Referring to FIGS. 16 to 21, a die attach process may be performed to sequentially stack a plurality of semiconductor chips 200 on the upper surface 102 of the package substrate 100. Additionally, a wire bonding process as a thermosonic method may be performed to form the plurality of bonding wires 230 to electrically connect the package substrate 100 to the plurality of semiconductor chips 200.

As illustrated in FIG. 16, a first semiconductor chip as the lowest semiconductor chip 200a may be attached by a first adhesive film 220a on the upper surface 102 of the package substrate 100. The first semiconductor chip 200a may be stacked on the upper surface 102 of the package substrate 100 such that the first surface 202 including chip pads 210a are formed faces upward. A die attach process may be performed to attach the first semiconductor chip 200a on the upper surface 102 of the package substrate 100 by using a first adhesive film 220a, such as a die attach film (DAF). For example, the first semiconductor chip 200a may be attached on the upper surface 102 of the package substrate 100 through a thermal compression process. The first semiconductor chip 200a may be pressed by a die attaching tool and heated to a high temperature by a heater block in a support system supporting the package substrate 100.

The first semiconductor chip 200a may be disposed adjacent to the second side S12 of the package substrate 100. The first semiconductor chip 200a may be spaced apart from the dam structure 130 of the package substrate 100 in the first direction (X direction). The first semiconductor chip 200a may be disposed such that a backside surface 204, that is an inactive side, faces the package substrate 100 opposite to the front surface 202 where the plurality of first chip pads 210a are formed.

The first semiconductor chip 200a may have a rectangular shape with four sides when viewed in a plan view. For example, the first semiconductor chip 200a may include a first side S31 extending in the second direction (Y direction) and a second side S32 facing (e.g. opposite) the first side S31. The plurality of first chip pads 210a may be disposed on the front surface 202 of the first semiconductor chip 200a along the first side S31 to expose at least one surface.

The first semiconductor chip 200a may include a memory chip including a memory circuit. For example, the plurality of semiconductor chips 200 may include volatile memory devices such as SRAM devices or DRAM devices and a non-volatile memory device such as flash memory devices, PRAM devices, MRAM devices or RRAM devices. Alternatively, the first semiconductor chip 200a may include a logic chip having a logic circuit. The logic chip may be a controller that controls memory chips. The logic chip may be a processor chip such as an ASIC or an application processor (AP) as a host such as a CPU, GPU, or SOC.

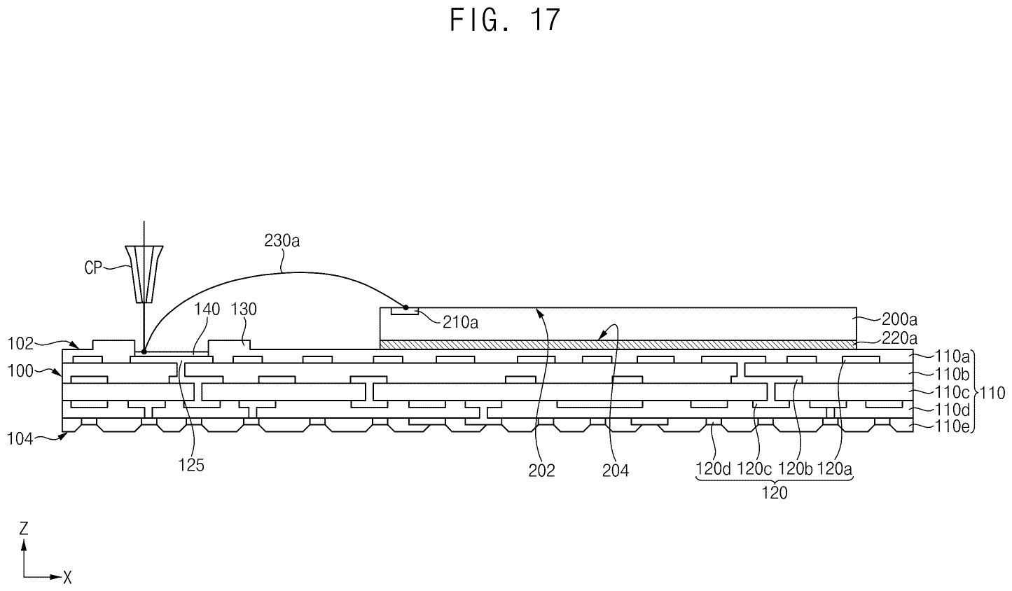

As illustrated in FIG. 17, first bonding wires 230a may be formed to be electrically between (e.g. electrically connect) each of the plurality of the first chip pads 210a of the semiconductor chip 200a and each of the plurality of substrate pads 140 of package substrate 100.

For example, a conductive wire may be dispensed from a capillary (CP). An end portion of the dispensed conductive wire in a ball shape may be in contact with the first chip pad 210a. By generating ultrasonic waves in the capillary (CP) and heating the package substrate 100, the end portion of each of the plurality of first bonding wires 230a may be bonded to each of the plurality of chip pads 210. And then, another end portion of each of the plurality of first bonding wires 230a may be bonded to each of the plurality of substrate pads 140 in the same manner.

The first semiconductor chip 200a may be electrically connected to the package substrate 100 by the plurality of first bonding wires 230a. For example, the plurality of first bonding wires 230a may include a metal material. For example, the bonding wires 230 may include gold (Au).

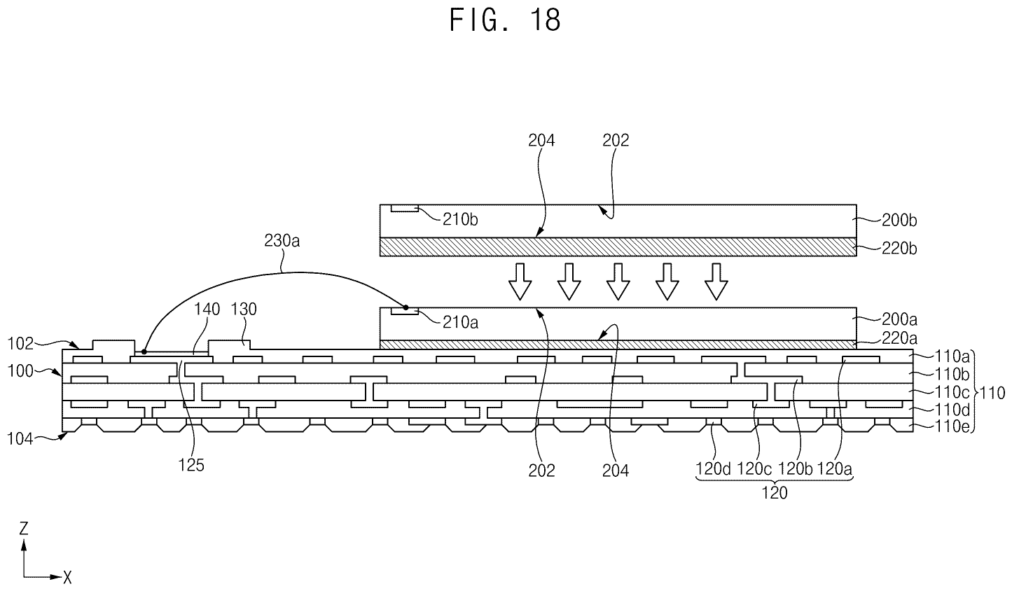

As illustrated in FIGS. 18 and 21, by performing the same or similar processes as described above with reference to FIGS. 16 and 17, the second to fourth semiconductor chips 200b, 200c, and 200d may be attached on the first semiconductor chip 200a by the second to fourth adhesive films 220b, 220c, and 220d, and then the plurality of second to fourth bonding wires 230b, 230c, and 230d may be formed by the wire bonding process as the thermosonic method.

In particular, the second to fourth semiconductor chips 200b, 200c and 200d may be sequentially attached on a front surface 202 of the first semiconductor chip 200a by the die attach process. Also, the plurality of second to fourth bonding wires 230b, 230c and 230d may be formed by the thermosonic method using a conductive material to be electrically connected between each of the plurality of substrate pads 140 and each of the plurality of second to fourth chip pads 210b, 210c and 210d. In some example embodiments as depicted in FIG. 21, each individual substrate pad 140 may be connected to a respective chip pad 210 by a respective bonding wire 230.

The number, size and the arrangement, etc. of the plurality of semiconductor chips 200 are provided as examples, and the present invention is not limited thereto. Also, although only a few chip pads are shown in the drawings, it will be understood that the structure, shape, and arrangement of the chip pads are provided as examples, and the present invention is not limited thereto.

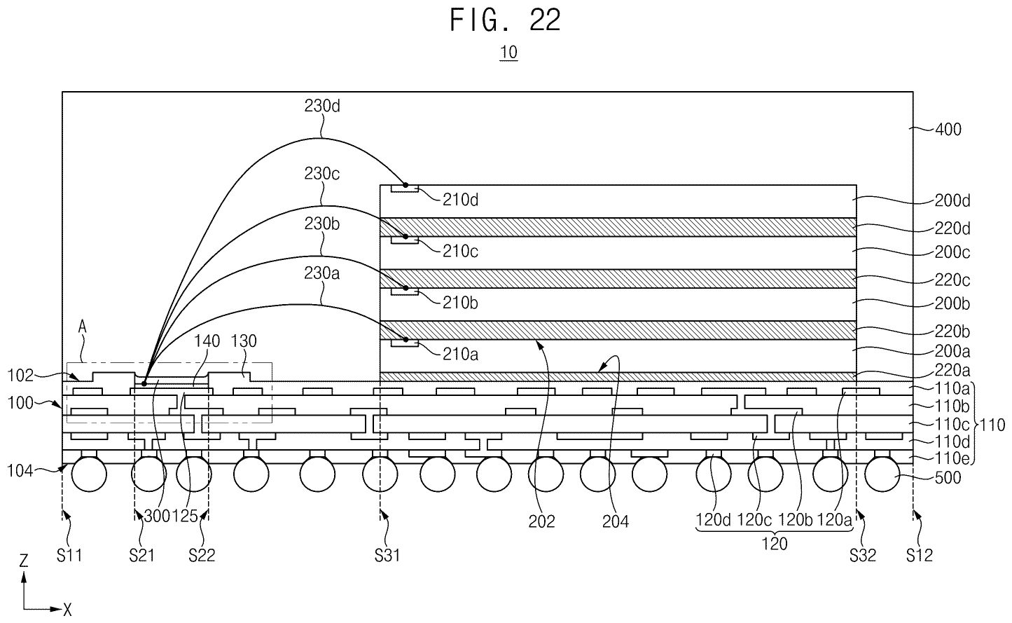

Referring to FIG. 22, an underfill member 300 at least partially filling the recess R of the package substrate 100 may be formed to cover the end portions of the plurality of bonding wires 230 bonded to the plurality of substrate pads 140. Subsequently, a molding member 400 may be formed on the upper surface 102 of the package substrate 100 to cover the plurality of semiconductor chips 200 and the plurality of bonding wires 230. For example, the molding member may include EMC (Epoxy Molding Compound). And, a plurality of external connection members 500 may be formed on the plurality of fourth wires as external connection pads 120d on the lower surface 104 of the package substrate 100, so the semiconductor package 10 of FIG. 1 may be completed. For example, the plurality of external connection members 500 may include solder balls. The plurality external connection members 500 may be formed by a solder ball attach process.

The underfill member 300 may include a thermosetting material that has fluidity before being heated, but hardens after being heated. For example, the underfill member 300 may include an adhesive material including an epoxy material.

For example, by using a dispensing apparatus providing at least one dispensing unit, the recess R of the package substrate 100 may be filled with an epoxy material. Since the at least one dispensing unit forms the underfill member 300 without being contact with the plurality of bonding wires 230, external force acting on the plurality of bonding wires 230 during the process may be minimized or reduced.

The underfill member 300 may reinforce a connection between the plurality of bonding wires 230 and the plurality of substrate pads 140. For example, the underfill member 300 may secure the end portions of the plurality of bonding wires to prevent or reduce in likelihood external force from acting on the connection between the plurality of bonding wires 230 and the plurality of substrate pads 140.

The underfill member 300 may be in contact with the dam structure 130 of the package substrate 100. The dam structure 130 may prevent or reduce in likelihood the underfill member 300 which has fluidity from overflowing out of the recess R of the package substrate 100 before the underfill member 300 is heated.

The semiconductor package may include semiconductor devices such as logic devices or memory devices. The semiconductor package may include logic devices such as central processing units (CPUs), main processing units (MPUs), or application processors (APs), or the like, and volatile memory devices such as DRAM devices, HBM devices, or non-volatile memory devices such as flash memory devices, PRAM devices, MRAM devices, ReRAM devices, or the like.

The foregoing is illustrative of some example embodiments and is not to be construed as limiting thereof. Although a few example embodiments have been described, those skilled in the art will readily appreciate that many modifications are possible in example embodiments without materially departing from the novel teachings and advantages of the present inventive concepts. Accordingly, all such modifications are intended to be included within the scope of example embodiments as defined in the claims.

What is claimed is:

1. A semiconductor package, comprising:
a package substrate including a plurality of substrate pads spaced apart from each other in a first direction and an upper insulation layer on an upper surface of the package substrate, the upper insulation layer defining a recess that exposes the plurality of substrate pads;
a dam structure extending on the upper insulation layer to surround the recess;
a plurality of semiconductor chips stacked on the upper insulation layer, the plurality of semiconductor chips each including a first surface facing upwards and each chip pad of a plurality of chip pads on a respective first surface, the plurality of semiconductor chips being spaced apart from the dam structure in a second direction perpendicular to the first direction;
a plurality of bonding wires connecting the plurality of substrate pads to the plurality of chip pads of the plurality of semiconductor chips; and
an underfill member filling an interior of the recess to cover an end portion of each of the plurality of bonding wires and each of the plurality of substrate pads.

2. The semiconductor package of claim 1, wherein the dam structure has a first height from the upper surface of the package substrate.

3. The semiconductor package of claim 2, wherein the first height is within a range of 5 μm to 10 μm.

4. The semiconductor package of claim 1, the dam structure has a first width from an inner wall of the recess.

5. The semiconductor package of claim 4, wherein the first width is within a range of 50 μm to 150 μm.

6. The semiconductor package of claim 1, wherein the plurality of semiconductor chips are sequentially attached on the upper surface of the package substrate by a plurality of adhesive films.

7. The semiconductor package of claim 1, wherein each of the plurality of substrate pads has a first conductive layer and a second conductive layer on the first conductive layer.

8. The semiconductor package of claim 7, wherein the first conductive layer includes nickel (Ni), and the second conductive layer includes gold (Au).

9. The semiconductor package of claim 1, wherein
the dam structure includes an insulation material, and
the insulation material and the upper insulation layer include a same material.

10. The semiconductor package of claim 1, wherein
the upper insulation layer exposes a portion of each of a plurality of uppermost wires in the package substrate, and
wherein each of the plurality of substrate pads is on a respective exposed portion of the plurality of uppermost wires.

11. A semiconductor package, comprising:
a package substrate having a first side portion extending in a first direction and a second side portion facing with the first side portion, the package substrate having a plurality of substrate pads spaced apart from each other along the first side portion and an upper insulation layer defining a recess that exposes the plurality of substrate pads;
a dam structure extending on the upper insulation layer to surround the recess;
a plurality of semiconductor chips stacked on an upper surface of the package substrate such that a first surface on which a plurality of chip pads are formed faces upward, the plurality of semiconductor chips being spaced apart from a side portion of the dam structure in a second direction perpendicular to the first direction;
a plurality of bonding wires connecting the plurality of substrate pads to the plurality of chip pads of the plurality of semiconductor chips; and
an underfill member filling an interior of the recess to cover an end portion of each of the plurality of bonding wires and each of the plurality of substrate pads.

12. The semiconductor package of claim 11, wherein the dam structure has a first height from the upper surface of the package substrate.

13. The semiconductor package of claim 12, wherein the first height is within a range of 5 μm to 10 μm.

14. The semiconductor package of claim 11, the dam structure has a first width from an inner wall of the recess.

15. The semiconductor package of claim 14, wherein the first width is within a range of 50 μm 150 μm.

16. The semiconductor package of claim 11, wherein the plurality of semiconductor chips are sequentially attached on the upper surface of the package substrate by a plurality of adhesive films.

17. The semiconductor package of claim 11, wherein each of the plurality of substrate pads has a first conductive layer and a second conductive layer disposed on the first conductive layer.

18. The semiconductor package of claim 11, wherein
the dam structure includes an insulation material, and
the insulation material and the upper insulation layer include a same material.

19. The semiconductor package of claim 11, wherein
the upper insulation layer exposes a portion of each of a plurality of uppermost wires, and
wherein each of the plurality of substrate pads is disposed on the exposed portion of each of the plurality of uppermost wires.

20. A semiconductor package, comprising:
a package substrate having a plurality of uppermost wires and an upper insulation layer on an upper surface of the package substrate, the upper insulation layer defining a recess exposing the plurality of uppermost wires, a plurality of substrate pads on the plurality of exposed uppermost wires, and a dam structure extending on the upper insulation layer to surround the recess;
a plurality of semiconductor chips stacked on the upper surface of the package substrate by a plurality of adhesive films such that a first surface on which a plurality of chip pads are formed faces upward;
a plurality of bonding wires connecting the plurality of substrate pads to the plurality of chip pads of the plurality of semiconductor chips; and
an underfill member filling an interior of the recess to cover an end portion of each of the plurality of bonding wires and each of the plurality of substrate pads.
